(19) United States
(12) Patent Application Publication
(10) Pub. No.: US 2005/0068213 A1
(43) Pub. Date: Mar. 31, 2005

(54) Digital compensation of excess delay in continuous time sigma delta modulators

(76) Inventors: Paul-Aymeric Fontaine, Plano, TX (US); Ahmed Nader Mohieldin, Richardson, TX (US)

Correspondence Address: TEXAS INSTRUMENTS INCORPORATED, P O BOX 655474, M/S 3999, DALLAS, TX, 75265, US

(21) Appl. No.: 10/903,608

(22) Filed: Jul. 29, 2004

Related U.S. Application Data
(60) Provisional application No. 60/505,901, filed on Sep. 25, 2003.

(51) Int. Cl. H03M 3/00

(52) U.S. Cl. 341/143

(57) ABSTRACT

A continuous time sigma delta modulator having minimal excess loop delay. The continuous-time sigma delta modulator in accordance with the present invention includes at least one integrator stage coupled to receive an input signal and a resultant integrator output signal from a previous stage for providing a resultant integrator output. At least one output stage connects to the at least one integrator stage to receive the resultant integrator output signal from the previous integrator stage for providing a resultant integrator output. A sample and hold circuit connects to receive the second integrator input signal. A multiplier connects to the sample and hold circuit to provide a resultant sampled signal. An analog-to-digital converter quantizer couples to receive the resultant sampled signal and to produce a quantized output signal. A digital modulation loop circuit connects to the analog-to-digital converter quantizer to generate a resultant quantized output signal for correcting excess loop delay in the continuous time sigma delta modulator. A fourth feedback multiplier coupled to receive the resultant quantized output signal and produce a second resultant quantized output signal. A digital-to-analog converter coupled to receive the second resultant quantized output signal to produce a modulation feedback signal. A delay connects to the digital-to-analog converter to receive the modulation feedback signal and provide the resultant modulation feedback signal

### FIELD OF THE INVENTION

The present invention relates to sigma delta modulators, and, more particularly, to a digital compensation of excess delay in a continuous time sigma delta converter.

### BACKGROUND OF THE INVENTION

Conversion of analog signals to digital signals and vice versa interfaces real world systems with digital systems that read, store, interpret, manipulate and otherwise process the discrete values of sampled analog signals, many of which vary. Real world applications that convert digital signals to analog waveforms at a high resolution include systems such as, high performance audio applications, high precision medical instrumentations, codec for wireless transceiver, digital audio systems, compact disc players, digital video players, and various other high performance audio applications.

Sigma-delta modulators (SDMs) have come into widespread use as a processing solution regarding these real world digital audio applications to provide a high resolution data conversion solution using low resolution building blocks. A low resolution building block, such as the single-bit DAC, provides perfect linearity which the single-bit SDM relies upon to achieve high resolution. In addition, the single-bit SDM has low sensitivity to analog component matching and large over-sampling ratios (OSRs), making it the preferred architecture for the past decade. These large OSRs arise from the inherent linearity of the single-bit DAC and the extremely small input bandwidth.

Oversampling sigma-delta ADCs are traditionally used in instrumentation, seismic, voice, and audio applications, with low signal bandwidth and high resolution. As disclosed in “A Continuous-Time ΣΔ Modulator With 88-dB Dynamic Range and 1.1-MHz Signal Bandwidth,” (Shouli Yan and Edgar Sanchez-Sinencio, IEEE Journal of Solid-State Circuits, Vol. 39, No. 1, January 2004), which is incorporated by reference herein, given enhancements in CMOS technology and architecture/circuit design techniques, sigma-delta ADCs have higher input signal bandwidth and medium to high resolution (12-16 bits). In addition, sigma-delta ADCs are greatly utilized in wireless and wireline communication applications. Initially, most sigma-delta modulators were based on switched-capacitor circuit techniques; yet, sigma-delta modulators having continuous-time loop filters can achieve higher clock frequency and consume less power.

Generally sigma-delta modulators, having signal bandwidth up to tens of kilohertz, include OSRs ranging from 64 to 256. To increase the signal bandwidth up to the megahertz range, not only must the clock frequency increase, but also the OSR must be reduced to that less than 64. In an effort to improve resolution at low OSR, however, the implementation must include a higher order loop filter or increase the internal quantizer resolution. Higher order loops, however, cause instability problems, resulting in reduced input range. In an effort to maintain stability, single-bit single loop modulators require that the integrator gain be reduced when the loop order is increased. Only a small SNR improvement, however, may be obtained by simply increasing the loop filter.

In contrast, the use of multiloop Multi-bit SDMs (MASH) topologies having two or three cascaded loops of first-order and/or second order modulators, solve the stability problem of single-loop higher order modulators. MASH topologies relax the instability problem and require lower oversampling ratios (OSRs). The MASH architecture can provide a signal to quantization noise ratio (SQNR) greater than 16 bits even with OSRs as low as 8. The conventional MASH architecture includes a one-bit ADC and a one-bit DAC in its feedback path. In addition, high resolution may also be obtained through the use of a multibit internal quantizer which has less non-linearity. Thereby, the stability of multibit multiloop sigma-delta greatly improves.

Previously, most sigma-delta modulators having a wide bandwidth wherein the signal bandwidth is greater than 200 KHz were implemented using switched capacitor circuit techniques. Switch capacitor circuits, however, have drastic settling accuracy requirements requiring high bandwidth active devices consuming large current. Continuous time sigma-delta modulators, however, have more relaxed settling requirements and can operate at higher clock frequency with less power consumption. In addition, continuous time sigma-delta modulators are beneficial due to the intrinsic antialiasing filter. As shown in FIGS. 1 and 5(a), the input signal is sampled after being filtered through the continuous time loop filter. The continuous-time sigma-delta modulator includes a loop filter coupled to receive an analog input through a summer. A sampler connects between the loop filter and a quantizer. The output of the quantizer is fed back into a DAC that provides input to the summer. Thereby, the continuous time loop filter suppresses a significant portion of the signal corresponding to aliasing frequencies. Moreover continuous time sigma delta modulators have relaxed sampling network requirements since the sampler is inside the noise shaping loop. Thereby, any sampling error is suppressed by the high gain of the loop filter in the bandwidth of interest.

As illustrated in FIG. 1, a third order sigma-delta modulator includes a series of cascaded integrators followed by a high speed quantizer, having a few levels. Feedback is provided to the cascaded integrators. Continuous-time modulators, however, have a few disadvantages. The first disadvantage is that continuous-time modulators are more sensitive to clock jitter. Many implement the use of multibit nonreturn-to-zero (NRZ) DAC pulse shaping to minimize clock jitter sensitivity and improve resolution. Continuous-time modulators, however, have another substantial performance disadvantage in that continuous-time modulators include non-zero excess loop delay. This non-zero excess loop delay presents a significant performance issue specifically when a NRZ feedback DAC is utilized within the continuous-time modulator since both the ADC and DAC have a zero input-output time delay requirement. SNR degradation and instability may result if the excess loop delay is too large. In particular, as shown in FIG. 2, when a constant delay τ_{d} is swept from 0 to τₛ/4, the SQNR results in substantial degradation for delays higher than τₛ/10. Moreover, since the nature of a sigma delta modulator is similar to an oscillator, it is very easy to make this modulator unstable in that it will start oscillating in an undesirable way. One way to mitigate this effect, the delay can be minimized. The delay, however, is signal dependent wherein it depends upon the signal at the output of the last integrator and, thus, will cause distortion. Implementation of a delayed return-to-zero (RZ) DAC pulse shaping may be used to relax loop delay to a fraction of the clock period; yet, multibit RZ DACs are more sensitive to clock jitter than a NRZ DAC.

Another approach to compensate for excess loop delay generate a second clock that is delayed by less than 10%. If there is more than a 10% delay, there will be substantial SNR degradation. More over this solution adds jitter and, thus, is not an effective approach.

A third approach is simply not to resample the signal. Accordingly, the signal is transmitted as fast as possible to the DAC output and, as a result, the timing of the DAC command will be signal dependent. Having signal dependent timing, however, translates into total harmonic distortion (THD) at the output of the sigma delta converter. Specifically, if the output of the quantizer is not resampled using a clock, it will suffer signal dependent jitter. The comparator is characterized by an exponential settling. The delay of the quantizer latch (back to back inverters) is a linear function of its time constant rs and logarithmic function of the initial input voltage difference ΔVin, as shown in equation (2):

$${τ}_{d} = {τ}_{s} ln ( \frac{{V}_{dd}}{Δ {V}_{in}} ) \qquad ( 2 )$$

In operation, if positive feedback is added, the difference ΔVᵢₙ increases exponentially; and hence, the delay is dependent upon the signal amplitude at the input of the quantizer. If the difference ΔVᵢₙ is very small, the quantizer will take more time through the exponential settling to resolve whether it's positive or negative. The larger the difference ΔVᵢₙ, the faster the original value of the voltage supply will be obtained. Disadvantageously, since the time delay is dependent upon the signal, there will be THD.

In another approach to minimize degradation from excess loop delay from a continuous-time sigma-delta ADC, the actual implemented delay-free transfer function F′(s) is derived and represented in terms of the desired transfer function F(s) as follows:
e^{-sτ}^{_{d}}F′(s)=F(s) (1)
where τ_{d} is the extra loop-delay. A finite pure delay is placed in the feedback in an effort to modify the transfer function of the continuous-time sigma delta. Pure delay, however, cannot be represented by a finite number of poles and zeros. Therefore, an exact solution in the s-domain is not possible. Fortunately, it is not necessary to solve F(s) for all frequencies. Samples may be taken from 0 to ƒₛ/2, which represents the Nyquist rate.

If the transfer function order increases from the desired transfer function F(s) to the actual implemented transfer function F′(s), the sigma delta converter order will increase accordingly. Increasing the order of the sigma delta converter, however, will increase the complexity and power consumption without SNR improvement increase the SNR degradation. Thus, the approximation of the actual transfer function F′(s) needs to be found without increasing the order.

Using this approach, the objective for stabilization purposes is to find the actual transfer function F′(s) and add a new feedback path in the analog domain as shown in FIG. 3. Matching both transfer functions F′(s) and F(s)e^{+τ}^{_{d}}^{s} for the low frequency components from 0 to ƒₛ/2 should produce two systems that are equivalent. Thereby, since there is no need to match both transfer functions for all frequencies, there is a substantial performance improvement.

Given, the delay free transfer function, F(s), must include (n−1) zeros and (n) poles, wherein (n−1) zeros represents the numerator function N(s) and (n) poles represents the denominator function D(s). To insure the stability of the continuous time loop, the number of zeros cannot exceed the number of poles. Accordingly, the actual transfer function F′(s) must include (n) zeros and (n) poles. In other words, the numerator function divide by the denominator function must represent a fraction. For a pure delay, however, an infinite number of zeros and poles are required. If, however, one pole or more than one zero is added, the order will increase; and, thereby the instability of the filter will increase. In the alternative, if one zero is added, the order of the sigma delta filter will not increase. This solution corrects the problem without increasing the complexity for the circuit.

In order generate the actual transfer function F′(s), there are four methods commonly used that include but are not limited to, modified z-transform, pade approximation, partial fraction and optimization, wherein optimization is the most robust method for low frequency implementation.

The modified z-transform can evaluate a sampled function between sampling points and/or insert a delay T_{d} before the sampler. Function F(s) time advanced, by shifting the time function F(s) to the left by Tₛ−T_{d}, wherein time delay Tₛ is the amount of time shifted. Following, the shifted time function F(s)e^{(Ts-Td)} is sampled by an ideal sampler starting from time t=0.3 seconds. The sampled sequence is then shifted to the right by one sampling instant Tₛ. This method, however, is difficult to automate and is not reliable.

The pade method approximates the continuous-time delay e^{+Ts} by expanding the function F(s) as a ratio of two power series and determining both the numerator and denominator coefficients. This method, however, increases the order of the transfer function.

The residue method generates a partial fraction expansion (i.e., a sum of terms in the form of a ratio of two polynomials (b/(a+s)). This ratio presents a simple solution for finding the sampled delay version of the first order transfer functions that make up the ratio. When results are summed back to a single expression, however, the final order increases.

The optimization method provides a robust way to match the shifted time transfer function F(s)e^{Tds}. The location of the n zeros and n poles are left as a degree of freedom that the algorithm can change to optimize a FOM (Figure Of Merit). For this purpose a typical FOM can be the RMS (Root Mean Square) difference of the shifted time transfer function F(s)e^{Tds} and actual transfer function F′(s). The FOM can be tailored to improve matching at low frequencies rather than high frequencies and produce a last feedback coefficient close to an integer value.

Using one of the four previously described methods, the coefficient is derived for the extra feedback as shown in FIG. 3 where extra feedback having coefficient a₄ is added to the conventional sigma-delta structure. FIG. 4 shows the Fast Fourier Transform of the sigma-delta modulator displayed in FIG. 3. The sigma-delta modulator has a SNR of 90 dB, which matches the ideal structure for F(s) with no excess delay.

This design is successful in minimizing the SNR and THD; however, the complexity of the design implementation incurs a substantial cost. Specifically, in “A Continuous-Time ΣΔ Modulator with 88 dB Dynamic Range and 1.1 MHz Signal Bandwidth,” (Shouli Yan and Edgar Sanchez-Sinencio, IEEE 2004), the proposed design generates another clock and an additional DAC (see FIGS. 5b and 5c). This approach and implementation using an analog delay may increase the distortion of the signal as well.

The present invention is directed to overcoming, or at least reducing the effects of one or more of the problems set forth above.

### SUMMARY OF THE INVENTION

To address the above-discussed deficiencies of continuous time sigma delta modulators, the present invention teaches a continuous time sigma delta modulator having minimal excess loop delay. The continuous-time sigma delta modulator in accordance with the present invention includes at least one integrator stage coupled to receive an input signal and a resultant integrator output signal from a previous stage for providing a resultant integrator output. At least one output stage connects to the at least one integrator stage to receive the resultant integrator output signal from the previous integrator stage for providing a resultant integrator output. A sample and hold circuit connects to receive the second integrator input signal. A multiplier connects to the sample and hold circuit to provide a resultant sampled signal. An analog-to-digital converter quantizer couples to receive the resultant sampled signal and to produce a quantized output signal. A digital modulation loop circuit connects to the analog-to-digital converter quantizer to generate a resultant quantized output signal for correcting excess loop delay in the continuous time sigma delta modulator. A fourth feedback multiplier coupled to receive the resultant quantized output signal and produce a second resultant quantized output signal. A digital-to-analog converter coupled to receive the second resultant quantized output signal to produce a modulation feedback signal. A delay connects to the digital-to-analog converter to receive the modulation feedback signal and provide the resultant modulation feedback signal

Advantages of this design include but are not limited to a continuous time sigma delta converter that compensates for the excess delay in the feedback loop; wherein the analog compensation is transferred to the digital domain. This solution presents a small, simple and cost effective approach towards minimizing excess loop delay.

These and other features and advantages of the present invention will be understood upon consideration of the following detailed description of the invention and the accompanying drawings.

### BRIEF DESCRIPTION OF THE DRAWINGS

For a more complete understanding of the present invention and the advantages thereof, reference is now made to the following description taken in conjunction with the accompanying drawings in which like reference numbers indicate like features and wherein:

FIG. 1 illustrates a known continuous time sigma delta modulator;

FIG. 2 displays a graph of the signal-to-noise ration versus the delay for the known continuous time sigma delta modulator of FIG. 1;

FIG. 3 shows an known continuous time sigma delta modulator having an analog feedback loop to compensate for excess loop delay;

FIG. 4 displays the output spectrum for the continuous time sigma delta modulator of FIG. 3 in decibels versus frequency; and

FIG. 5(a) displays the known continuous time sigma delta modulator;

FIG. 5(b) shows a known continuous time sigma delta modulator having a feedback loop to compensate for excess loop delay;

FIG. 5(c) illustrates a detailed schematic of the continuous time sigma delta modulator of FIG. 5(b);

FIG. 6 shows the continuous time sigma delta modulator having a digital feedback loop to compensate for excess loop delay in accordance with the present invention; and

FIG. 7 displays the output spectrum for the continuous time sigma delta modulator of FIG. 6 in decibels versus frequency.

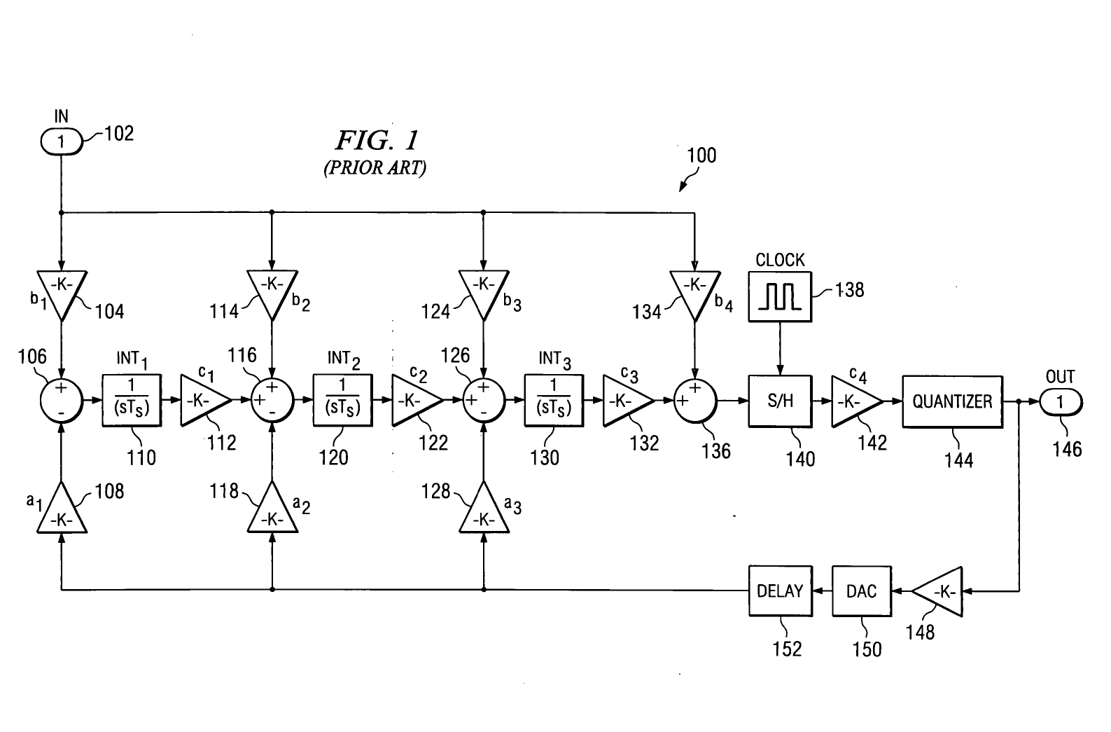

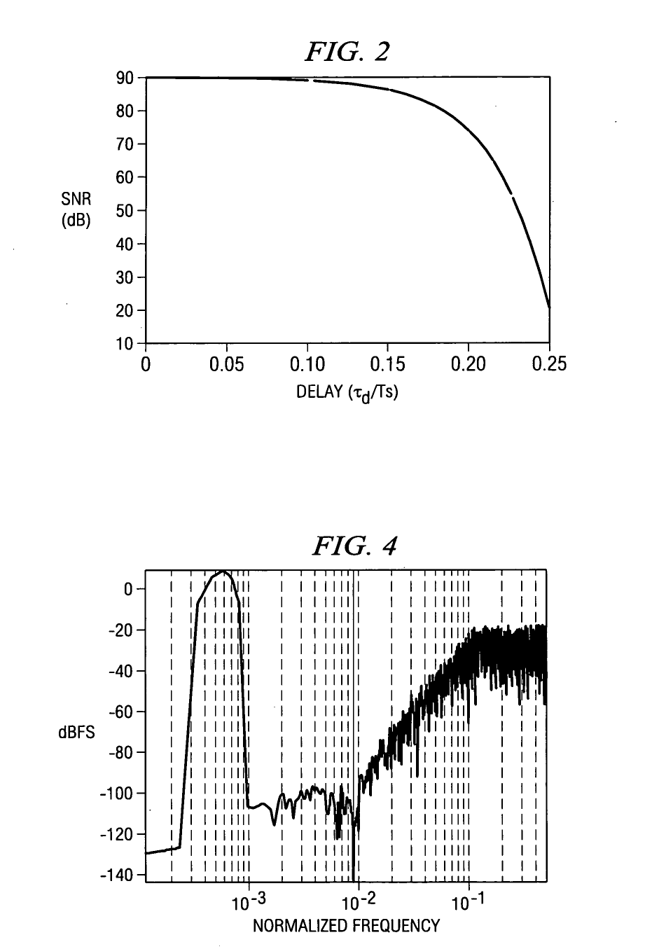

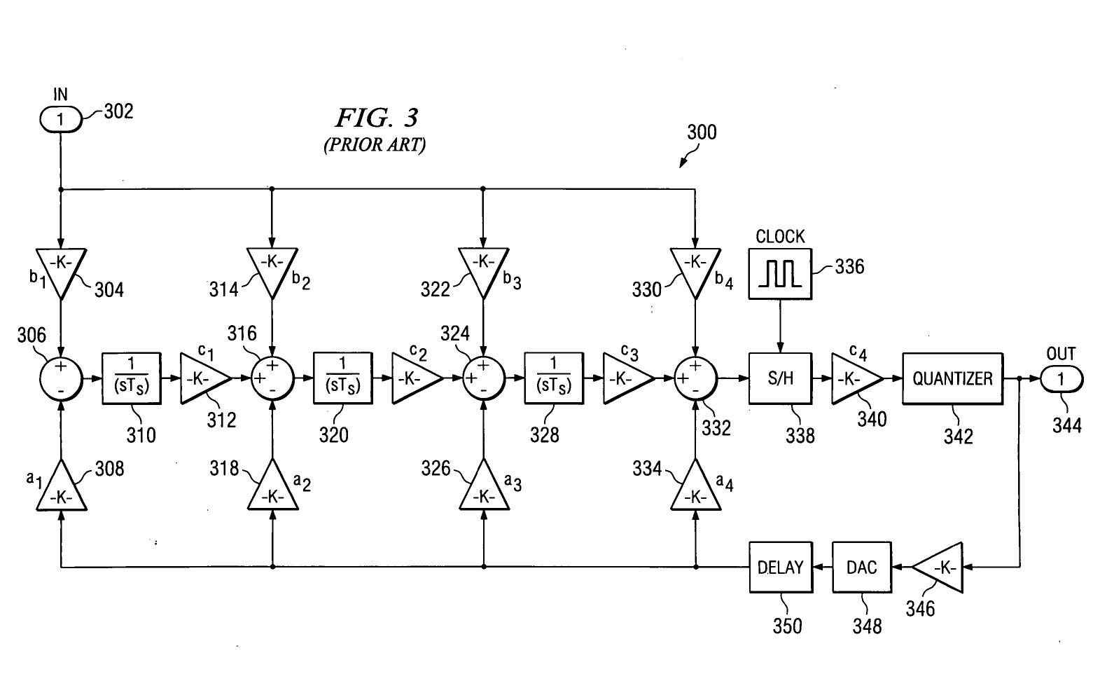

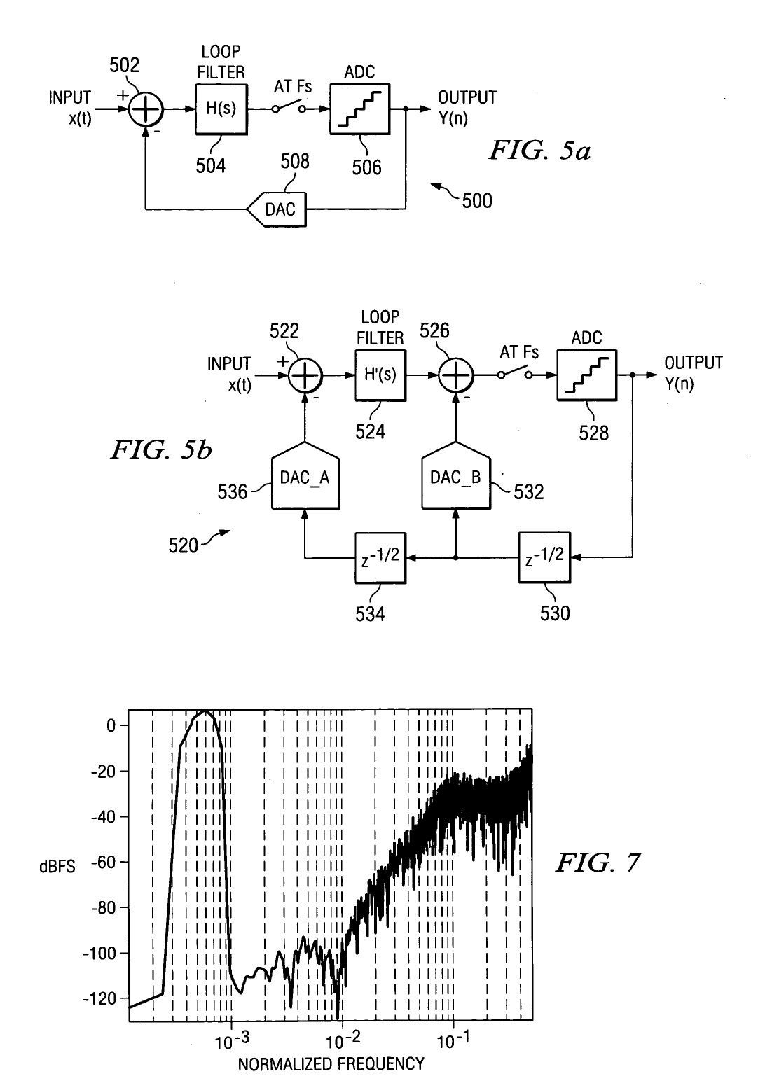

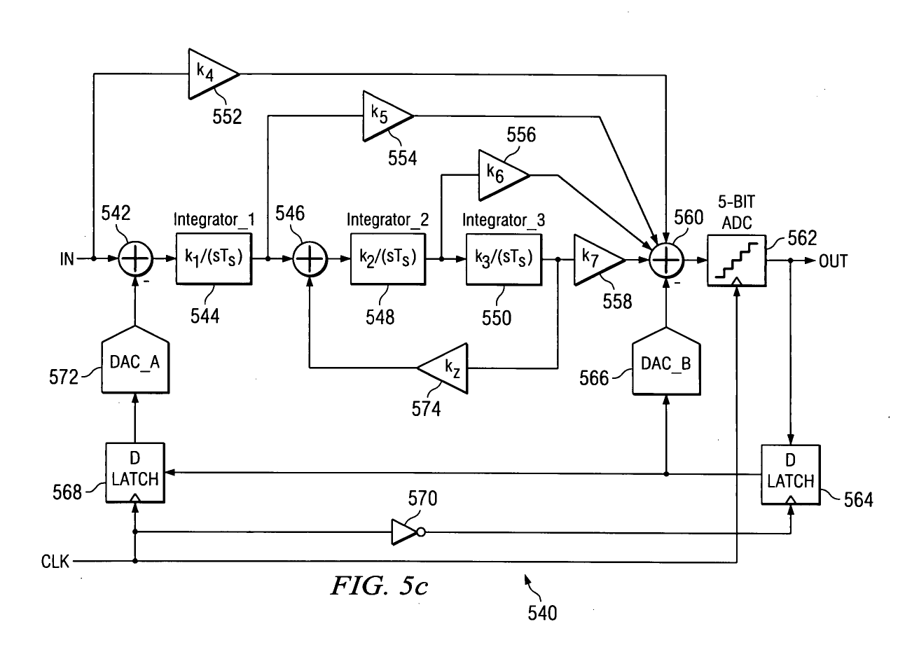

### DETAILED DESCRIPTION OF PREFERRED EMBODIMENTS

The present invention will now be described more fully hereinafter with reference to the accompanying drawings, in which embodiments of the invention are shown. This invention may, however, be embodied in many different forms and should not be construed as limited to the embodiments set for the herein. Rather, these embodiments are provided so that this disclosure will be thorough and complete, and will fully convey the scope of the invention to those skilled in the art.

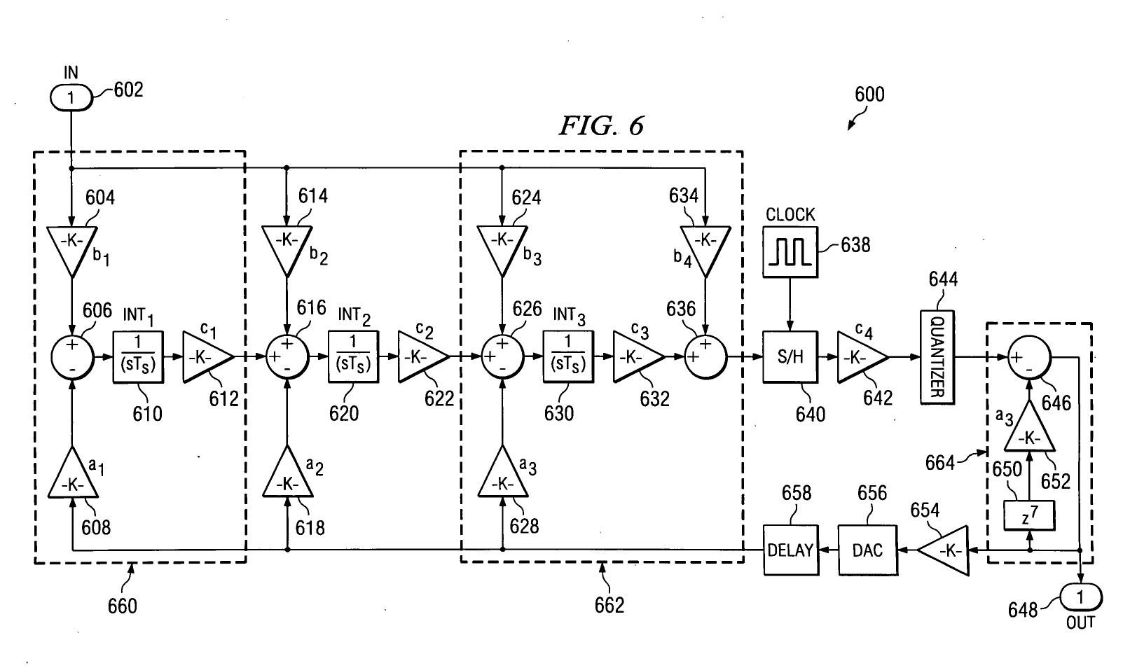

FIG. 6 illustrates the continuous time sigma delta converter in accordance with the present invention. As shown, continuous-time sigma delta modulator 600 in accordance with the present invention includes at least one integrator stage 660 coupled to receive an input signal and a resultant integrator output signal from a previous stage for providing a resultant integrator output. At least one output stage 662 connects to the at least one integrator stage 660 to receive the resultant integrator output signal from the previous integrator stage for providing a resultant integrator output. A sample and hold circuit 640 connects to receive the second integrator input signal. A multiplier 642 connects to the sample and hold circuit 640 to provide a resultant sampled signal. An analog-to-digital converter quantizer 644 couples to receive the resultant sampled signal and to produce a quantized output signal. A digital modulation loop circuit 664 connects to the analog-to-digital converter quantizer 644 to generate a resultant quantized output signal for correcting excess loop delay in the continuous time sigma delta modulator 600. A multiplier 654 coupled to receive the resultant quantized output signal and produce a second resultant quantized output signal. A digital-to-analog converter 656 coupled to receive the second resultant quantized output signal to produce a modulation feedback signal. A delay 658 connects to the digital-to-analog converter 656 to receive the modulation feedback signal and provide the resultant modulation feedback signal.

As shown, integrator stage 660 includes an input multiplier 604 coupled to receive the input signal to generate a resultant input signal. A feedback multiplier 608 coupled to receive a modulation feedback signal to generate a resultant modulation feedback signal. Adder 606 connects to input multiplier 604 and feedback multiplier 608 to calculate an integrator input signal as a difference between the resultant input signal, the resultant integrator output signal from the previous stage, and the resultant modulation feedback signal. A continuous time integrator 610 connects to receive the integrator input signal to integrate and produce an integrator output signal. An integrator multiplier 612 connects to receive the integrator output signal to provide the resultant integrator output signal. As is shown in FIG. 6, the continuous time sigma delta converter in accordance with the present invention is a third order sigma delta converter, wherein elements 614-622 form a second integrator stage.

Moreover, an output stage 662 includes a first input multiplier 624 connected to receive the input signal to generate a resultant input signal. A feedback multiplier 628 connects to receive a modulation feedback signal to generate a resultant modulation feedback signal. A first adder connects to the first input multiplier 624 and the feedback multiplier 628 to calculate a first integrator input signal as a difference between the resultant input signal, the resultant integrator output signal from the previous stage, and the resultant modulation feedback signal. A continuous time integrator 630 connects to receive the first integrator input signal to integrate and produce an integrator output signal having a common mode component. An integrator multiplier 632 connects to receive the integrator output signal to provide the resultant integrator output signal. A second input multiplier 634 connects to receive the input signal to generate a second resultant input signal. A second adder couples to the second input multiplier 634 and the integrator multiplier 632 to calculate a second integrator input signal as a difference between the second resultant input signal and the resultant integrator output signal.

Furthermore, a digital modulation loop circuit 664 includes an adder 646 coupled to receive the quantized output signal and a second modulated feedback signal to generate a resultant quantized output signal. A delay 650 couples to receive the resultant quantized output signal. A feedback multiplier 652 connects to the delay to receive the delayed resultant quantized output signal to provide the second modulated feedback signal.

The digital modulation loop circuit 664 provides digital feedback after the quantizer 644; in contrast to the analog implementation where the feedback input is placed just prior to quantizer 644. Each feedback coefficient has a different weight, a₁, a₂, a₃, and a₄^{d}. Part of the inventive concept is to make certain that the digital domain coefficient has an integer value. The known sigma delta modulator will include a quantizer of two levels and a correlated DAC of two levels. DAC must be linear to the ADC; thereby, having the same level. If the quantizer is two levels, it is relatively easy to implement the sigma delta with a two level DAC. If a₄^{d} is an integer and the input is an integer, the output will be a fraction. If a₄^{d} is an not integer, then the number of levels for the DAC will increase drastically. Increasing the level of the DAC increases the size and complexity of the DAC. When the feedback is incorporated in the digital domain, the aforementioned optimization scheme can be used to generate different coefficients that work with a₄^{d} that are not an integer. In the alternative, the optimization scheme can be used to find F′(s) close to F(s) e^{+τ}^{_{d}}^{s} such that a₄^{d} will be close to an integer.

Advantages of this design include but are not limited to a continuous time sigma delta converter that compensates for the excess delay in the feedback loop with minimum SNR or THD degradation; wherein the analog compensation is transferred to the digital domain. This solution presents a small digital implementation that is a simple and cost effective approach towards minimizing excess loop delay.

Those of skill in the art will recognize that the physical location of the elements illustrated in FIG. 6 can be moved or relocated while retaining the function described above.

The reader's attention is directed to all papers and documents which are filed concurrently with this specification and which are open to public inspection with this specification, and the contents of all such papers and documents are incorporated herein by reference.

All the features disclosed in this specification (including any accompany claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The terms and expressions which have been employed in the foregoing specification are used therein as terms of description and not of limitation, and there is no intention in the use of such terms and expressions of excluding equivalents of the features shown and described or portions thereof, it being recognized that the scope of the invention is defined and limited only by the claims which follow.

1. A continuous time sigma delta modulator, comprising:
at least one integrator stage coupled to receive an input signal and a resultant integrator output signal from a previous stage for providing a resultant integrator output;
at least one output stage coupled to receive the resultant integrator output signal from a previous at least one integrator stage for providing a resultant integrator output;
a sample and hold circuit coupled to receive the second integrator input signal to sample and hold the second integrator input signal;
a multiplier coupled to the sample and hold circuit to provide a resultant sampled signal;
an analog-to-digital converter quantizer coupled to receive the resultant sampled signal and to produce a quantized output signal;
a digital modulation loop circuit coupled to the analog-to-digital converter quantizer to generate a resultant quantized output signal for correcting excess loop delay in the continuous time sigma delta modulator;
a fourth feedback multiplier coupled to receive the resultant quantized output signal and produce a second resultant quantized output signal;
a digital-to-analog converter coupled to receive the second resultant quantized output signal to produce a modulation feedback signal; and
a delay coupled to the digital-to-analog converter to receive the modulation feedback signal and provide the resultant modulation feedback signal.

2. A continuous time sigma delta modulator as recited in claim 1, wherein the at least one integrator stage comprises:
an input multiplier coupled to receive the input signal to generate a resultant input signal,
a feedback multiplier coupled to receive a modulation feedback signal to generate a resultant modulation feedback signal;
an adder to calculate an integrator input signal as a difference between the resultant input signal, the resultant integrator output signal from the previous stage, and the resultant modulation feedback signal;
a continuous time integrator coupled to receive the integrator input signal to integrate and produce an integrator output signal having a common mode component; and
an integrator multiplier coupled to receive the integrator output signal to provide the resultant integrator output signal.

3. A continuous time sigma delta modulator as recited in claim 1, wherein the at least one output stage comprises:
an first input multiplier coupled to receive the input signal to generate a resultant input signal;
a feedback multiplier coupled to receive a modulation feedback signal to generate a resultant modulation feedback signal;
a first adder to calculate a first integrator input signal as a difference between the resultant input signal, the resultant integrator output signal from the previous stage, and the resultant modulation feedback signal;
a continuous time integrator coupled to receive the first integrator input signal to integrate and produce an integrator output signal having a common mode component;
an integrator multiplier coupled to receive the integrator output signal to provide the resultant integrator output signal;
a second input multiplier coupled to receive the input signal to generate a second resultant input signal; and
a second adder to calculate a second integrator input signal as a difference between the second resultant input signal and the resultant integrator output signal.

4. A apparatus as recited in claim 1, wherein the digital modulation loop circuit comprises,
an adder coupled to receive the quantized output signal and a second modulated feedback signal to generate a resultant quantized output signal;
a delay coupled to receive the resultant quantized output signal; and
a feedback multiplier coupled to receive the delayed resultant quantized output signal to provide the second modulated feedback signal.
